(19) United States
(12) Patent Application Publication
(10) Pub. No.: US 2012/0139023 A1
(43) Pub. Date: Jun. 7, 2012

(54) METHOD AND APPARATUS FOR NAND MEMORY WITH RECESSED SOURCE/DRAIN REGION

(75) Inventors: Chun CHEN, San Jose, CA (US); Angela T. Hui, Fremont, CA (US); Fei Wang, San Jose, CA (US)

(73) Assignee: Spansion LLC, Sunnyvale, CA (US)

(21) Appl. No.: 12/960,411

(22) Filed: Dec. 3, 2010

(51) Int. Cl. H01L 29/78; H01L 21/04; G06F 17/50

(52) U.S. Cl. 257/314; 716/100; 438/510; 257/E29.255; 257/E21.04

(57) ABSTRACT

A method and apparatus for a flash memory is provided. A NAND flash memory array includes a cell body, a first selective gate, and a first edge line. The cell body includes recessed doped source/drain region between the first selective gate and the first edge word line.

### TECHNICAL FIELD

The invention is related to computer-readable memory, and in particular, but not exclusively, to a method and apparatus for a NAND flash memory having a recessed source/drain region between a selective gate and an edge word line.

### BACKGROUND

Various types of electronic memory have been developed in recent years. Some exemplary memory types are electrically erasable programmable read only memory (EEPROM) and electrically programmable read only memory (EPROM). EEPROM is easily erasable but lacks density in storage capacity, where as EPROM is inexpensive and denser but is not easily erased. “Flash” EEPROM, or Flash memory, combines the advantages of these two memory types. This type of memory is used in many electronic products, from large electronics like cars, industrial control systems, and etc. to small portable electronics such as laptop computers, portable music players, cell phones, and etc.

Flash memory is generally constructed of many memory cells where a single bit is held within each memory cell. Yet a more recent technology known as MirrorBit™ Flash memory doubles the density of conventional Flash memory by storing two physically distinct bits on opposite sides of a memory cell. The reading or writing of a bit occurs independently of the bit on the opposite side of the cell. A memory cell is constructed of bit lines formed in a semiconductor substrate. An oxide-nitride-oxide (ONO) dielectric layer formed over top of the substrate and bit lines. The nitride serves as the charge storage layer between two insulating layers. Word lines are then formed over top of the ONO layer perpendicular to the bit lines. Applying a voltage to the word line, acting as a control gate, along with an applied voltage to the bit line allows for the reading or writing of data from or to that location in the memory cell array. MirrorBit™ Flash memory may be applied to different types of flash memory, including NOR flash and NAND flash.

### BRIEF DESCRIPTION OF THE DRAWINGS

Non-limiting and non-exhaustive embodiments of the present invention are described with reference to the following drawings, in which:

FIG. 1 illustrates a block diagram of an embodiment of a memory;

FIG. 2 shows a partial top plan view of an embodiment of core and peripheral sections of a memory that may be employed in the memory of FIG. 1;

FIG. 3 illustrates a block diagram of an embodiment of a NAND memory array;

FIG. 4 shows a cross-sectional side view of an embodiment of a core section of FIG. 2;

FIG. 5 illustrates an embodiment of a NAND memory cell array that may be a portion of an embodiment of the NAND memory array of FIG. 3;

FIG. 6 shows an embodiment of a NAND memory cell column of an embodiment of the NAND memory cell array of FIG. 5 during programming;

FIG. 7 illustrates an embodiment of a NAND memory cell column in fabrication after deposition of a cap;

FIG. 8 shows an embodiment of the NAND memory cell column of FIG. 7 after array spacer deposition and etch; and

FIG. 9 illustrates an embodiment of the NAND memory cell column of FIG. 7 after silicon recess etch, in accordance with aspects of the invention.

### DETAILED DESCRIPTION

Various embodiments of the present invention will be described in detail with reference to the drawings, where like reference numerals represent like parts and assemblies throughout the several views. Reference to various embodiments does not limit the scope of the invention, which is limited only by the scope of the claims attached hereto. Additionally, any examples set forth in this specification are not intended to be limiting and merely set forth some of the many possible embodiments for the claimed invention.

Throughout the specification and claims, the following terms take at least the meanings explicitly associated herein, unless the context dictates otherwise. The meanings identified below do not necessarily limit the terms, but merely provide illustrative examples for the terms. The meaning of “a,” “an,” and “the” includes plural reference, and the meaning of “in” includes “in” and “on.” The phrase “in one embodiment,” as used herein does not necessarily refer to the same embodiment, although it may. Similarly, the phrase “in some embodiments,” as used herein, when used multiple times, does not necessarily refer to the same embodiments, although it may. As used herein, the term “or” is an inclusive “or” operator, and is equivalent to the term “and/or,” unless the context clearly dictates otherwise. The term “based, in part, on”, “based, at least in part, on”, or “based on” is not exclusive and allows for being based on additional factors not described, unless the context clearly dictates otherwise. The term “coupled” means at least either a direct electrical connection between the items connected, or an indirect connection through one or more passive or active intermediary devices. The term “signal” means at least one current, voltage, charge, temperature, data, or other signal.

Briefly stated, the invention is related to a method and apparatus for a flash memory. A NAND flash memory array includes a cell body, a first selective gate, and a first edge line. The cell body includes recessed doped source/drain region between the first selective gate and the first edge word line.

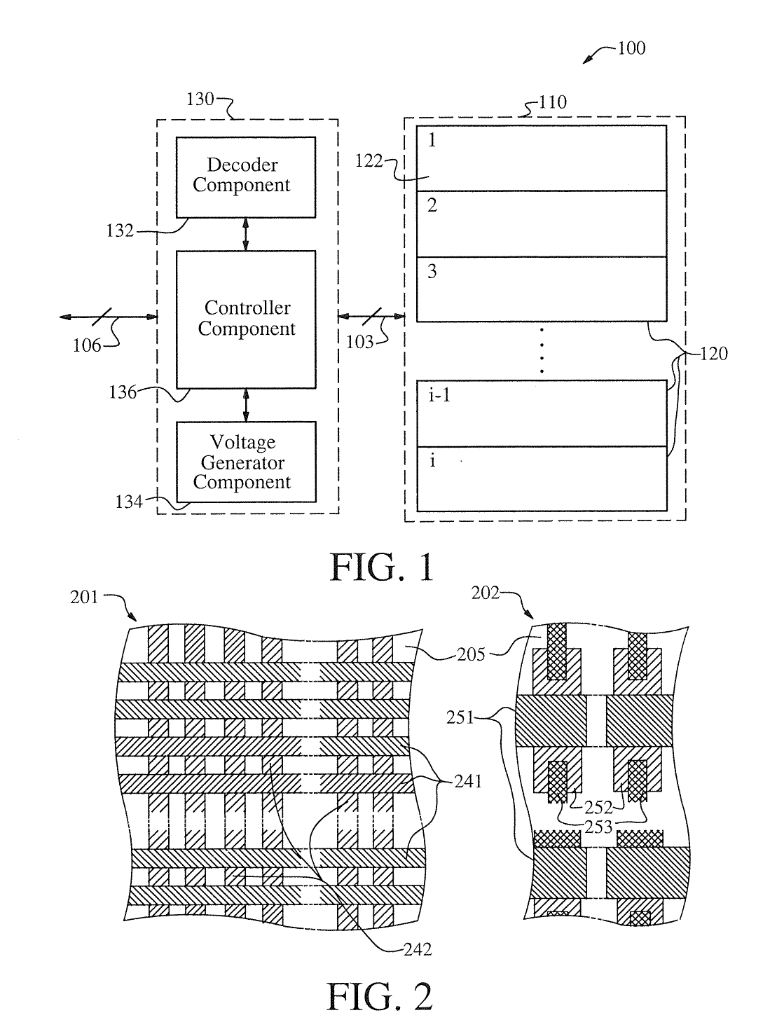

FIG. 1 shows a memory environment in which embodiments of the invention may be employed. Not all the components illustrated in the figures may be required to practice the invention, and variations in the arrangement and type of the components may be made without departing from the spirit or scope of the invention. For example, although described in the context of a flash-based memory, the fabrication described herein may be employed in manufacturing other types of microelectronic memories or devices other than memory in which a SONOS-like trap layer is employed.

As shown, memory 100 includes arrayed memory 110 and memory controller 130. Memory controller 130 is arranged to communicate addressing data and program data over signal path 106. For example, signal path 106 can provide 8, 16, or more I/O lines of data. Memory controller 130 is also configured to access arrayed memory 110 over signal path 103. For example, memory controller 130 can read, write, erase, and perform other operations at portions of arrayed memory 110 via signal path 103. In addition, although shown as single lines, signal path 103 and/or signal path 106 may be distributed across a plurality of signal lines and/or bus lines.

Arrayed memory 110 includes memory sectors 120 (identified individually as sectors 1-i) that can be accessed via memory controller 130. Memory sectors 120 can include, for example, 256, 512, 1024, 2048 or more sectors having memory cells that can be individually or collectively accessed. For example, in a NAND-based architecture, the individual memory cells are accessed collectively. In other examples, the number and/or arrangement of memory sectors can be different. In one embodiment, for example, sectors 120 can be referred to more generally as memory blocks and/or can be configured to have a configuration that is different than a bit line, word line, and/or sector topology.

Memory controller 130 includes decoder component 132, voltage generator component 134, and controller component 136. In one embodiment, memory controller 130 may be located on the same chip as arrayed memory 110. In another embodiment, memory controller 130 may be located on a different chip, or portions of memory controller 130 may be located on another chip or off chip. For example, decoder component 132, controller component 134, and voltage generator component 136 can be located on different chips but co-located on the same circuit board. In other examples, other implementations of memory controller 130 are possible. For example, memory controller 130 can include a programmable microcontroller.

Decoder component 132 is arranged to receive memory addresses via addressing signal path 106 and to select individual sectors, arrays, or cells according to the architecture of arrayed memory 110. In an NAND-based architecture, individual memory cells can be accessed collectively but not individually.

Decoder component 132 includes, for example, multiplexer circuits, amplifier circuits, combinational logic, or the like for selecting sectors, arrays, and/or cells based on any of a variety of addressing schemes. For example, a portion of a memory address (or a grouping of bits) can identify a sector within arrayed memory 110 and another portion (or another grouping of bits) can identify a core cell array within a particular sector.

Voltage generator component 134 is arranged to receive one or more supply voltages (not shown) and to provide a variety of reference voltages required for reading, writing, erasing, pre-programming, soft programming, and/or under-erase verifying operations. For example, voltage generator component 134 can include one or more cascode circuits, amplifier circuits, regulator circuits, and/or switch circuits that can be controlled by controller component 136.

Controller component 136 is arranged to coordinate reading, writing, erasing, and other operations of memory 100. In one embodiment, controller component 136 is arranged to receive and transmit data from an upstream system controller (not shown). Such a system controller can include, for example, a processor and a static random access memory (SRAM) that can be loaded with executable processor instructions for communicating over signal path 106. In another embodiment, controller component 136 as well as other portions of memory controller 130 may be embedded or otherwise incorporated into a system controller or a portion of a system controller.

Embodiments of controller component 136 can include a state machine and/or comparator circuits. State machine and comparator circuits can include any of a variety of circuits for invoking any of a myriad of algorithms for performing reading, writing, erasing, or other operations of memory 100. State machines and comparator circuits can also include, for example, comparators, amplifier circuits, sense amplifiers, combinational logic, or the like.

In one embodiment, memory 100 is a flash-based memory including flash-based memory cells, such as flash-based NAND cells, NOR cells, or hybrids of the two.

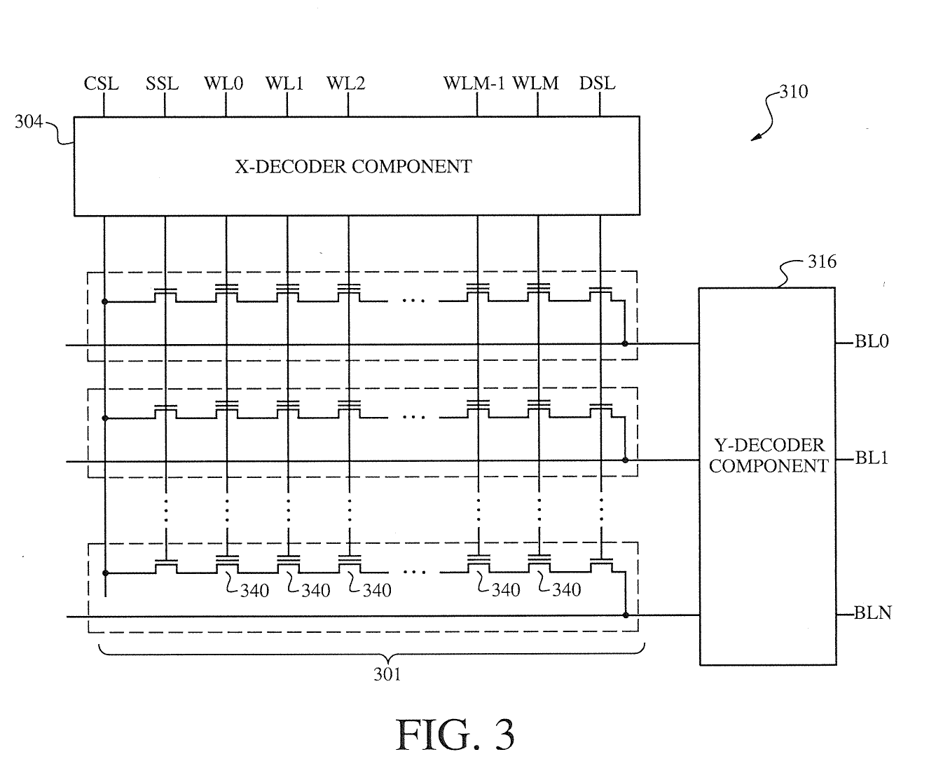

FIG. 2 shows a partial top plan view of separate sections of a memory. Core section 201, for example, may be an embodiment of a portion of sector 120 of FIG. 1 and may include arrayed core memory cells. Peripheral section 202, for example, may be an embodiment of memory controller 110 of FIG. 1 or a portion of memory controller 110 of FIG. 1.

Core section 201 includes core polysilicon lines 241, conductive regions 242, and a portion of substrate 205. Portions of core polysilicon lines 241 are coupled to the gates of individual memory cells (not shown in FIG. 2) and can be configured as a word line, a source select gate line, and/or a drain select gate line. Portions of conductive regions 242 can include, for example, p-type and/or n-type doped regions of substrate 205 for forming source/drain regions and/or conductive lines. For example, conductive regions 242 can form portions of bit lines and/or other signal lines. Also, in some embodiments, individual conductive regions 242 extend at least partially underneath individual core polysilicon lines 241.

In one embodiment, core section 201 is arranged in a NOR topology, and individual memory cells can be individually accessed via individual conductive regions 242. In another embodiment, core section 201 is arranged in a NAND topology, and individual memory cells can be accessed though individual conductive regions 242 collectively but not individually. In other embodiments, hybrid architectures can be employed. For example, core section 201 can be configured to have a portion that is NAND-based and another portion that is NOR-based. Also, although not shown if FIG. 2, core section 201 may include any of a variety of interconnect and/or passivation layers, such as dielectric, conductive, or other layers. For example, conductive regions 242 can be positioned beneath a dielectric spacer layer.

Peripheral section 202 includes peripheral polysilicon lines 251, conductive regions 252, and interconnects 253. Portions of peripheral polysilicon lines 251 are coupled to individual peripheral devices (not shown in FIG. 2).

Portions of conductive regions 252 can include, for example, p-type and/or n-type doped regions of substrate 205 for forming conductive features, such as a source, a drain, or other type of well. Interconnects 253 can include conductive lines that electrically intercouple portions of peripheral section 202 and/or electrically couple core section 201 with peripheral section 202. For example, interconnects 253 can include a combination of metal lines and vias. Also, although not shown FIG. 2, peripheral section 202 may also include any of a variety of other interconnect and/or passivation layers.

FIG. 3 illustrates a block diagram of an embodiment of a NAND memory array (310) that may be employed as an embodiment of memory array 110 of FIG. 1. Memory array 310 includes memory cells 340. Each memory cell 340 stores one or more bits of data. Memory array 310 can be associated with an X-decoder component 304 (e.g., word line (WL) decoder) and a Y-decoder component 316 (e.g., bit line (BL) decoder) that can each respectively decode inputs/outputs during various operations (e.g., programming, reading, verifying, erasing) that can be performed on the memory cells 340. The X-decoder component 304 and Y-decoder component 316 can each receive address bus information from memory controller 130 of FIG. 1, and can utilize such information to facilitate accessing or selecting the desired memory cell(s) (e.g., memory location(s)) associated with the command. The memory cells 340 can be formed in M rows and N columns. A common WL can be attached to the gate of each memory cell 340 in a row, such as word-lines WL0, WL1, WL2, through WLM. A common BL is attached collectively to cells 340, such as bit-lines BL0, BL1, through BLN as depicted in the respective diagrams. Respective voltages can be applied to one or more cells 340 through the WLs and BLs to facilitate performing operations, such as program, read, erase, and the like.

In some embodiments, the X-decoder component 304 is a WL encoder that receives a word line voltage that may be a relatively high boosted voltage. In this case, the X-decoder component 304 may contains transistors with high-voltage gate oxides. Other transistors in NAND memory array 310 that do not need such high voltages have low voltage gate oxides. The high voltage gate oxides need to be significantly thicker than the low voltage gate oxides due to the higher voltages that may be applied to the gate.

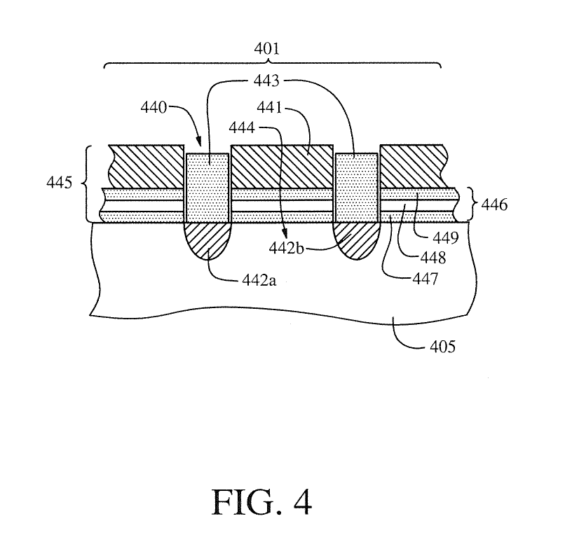

FIG. 4 shows a cross-sectional side view of a memory cell in core section 401. In one embodiment, core section 401 is an embodiment of core section 201 of FIG. 2.

Memory cell 440 includes a portion of substrate 405, dielectric spacer layer 443, channel region 444, source/drain regions 442a and 442b, and layered stack 445, including charge trapping component 446 and a portion of core polysilicon line 441. Substrate 405 may be an embodiment of substrate 205 of FIG. 2. Source/drain regions 442a and 442b may be an embodiment of one or more conductive regions 242 of FIG. 2. Core polysilicon line 441 may be an embodiment of an individual core polysilicon line 241 of FIG. 2.

In operation, core polysilicon line 441 and source/drain regions 442a and 442b are configured to provide electrical potential(s) to memory cell 440 for trapping charge at charge trapping component 446. A bit is “programmed” when it is trapping a charge and “unprogrammed” when it is not trapping charge. To trap charge, charge trapping component 446 employs tunneling layer 447, charge trapping layer 448, and dielectric layer 449. In general, tunneling layer 447 provides a tunneling barrier, charge trapping layer 448 is a layer that is configured to store charge, and dielectric layer 449 electrically isolates charge trapping layer 448 from core polysilicon line 441. In one embodiment, memory cell 440 is a one bit memory cell that is configured to store up to two logic states. In another embodiment, memory cell 440 can store more than two logic (or bit) states.

In some embodiments, charge trapping component 446 is an oxide-nitride-oxide (ONO) layer in which dielectric layer 449 is an oxide (such as silicon dioxide), charge trapping layer 448 is a nitride, and tunneling layer 447 is an oxide (such as silicon dioxide). In one embodiment in which charge trapping layer 448 is a nitride, charge trapping layer 448 may be a silicon-rich nitride (SIRN) such as silicon nitride.

Modern semiconductor devices are typically created as integrated circuits manufactured on the surface of a substrate of semiconductor material. The processing begins by growing a wafer, which is typically done using the Czochralski process. Various devices are formed on the wafer using a series of steps that include deposition, removal processes (such as etching), patterning, and doping. Few steps or many hundreds of such steps may be used in various designs. The patterning steps may be performed by photolithography or other lithographic methods. For example, the wafer may be coated with a photoresist, which is exposed with a device that exposes light through photomasking, exposing portions of the wafer not blocked by the photomask to light. The exposed regions are removed so that the photoresist remains only in areas that were not exposed to light. This allows a layer to be etched according to the pattern on the photomask. After the devices have been formed on the wafer, various back-end processing and packaging is performed, including properly interconnecting the devices and bringing metal lines to the chip edge for attachment to wires.

A designer creates the device design in accordance with a set of design rules provided by the fabricator, and creates a series of design files based on the design. Various design tools may be used by the designer in creating the design, simulating the design, and checking the design for layout rules violations. When completed, the design files are provided to the fabricator, which are used to generate photomasks for use in the fabricating the device. The design files may be communicated in different ways, including over a network.

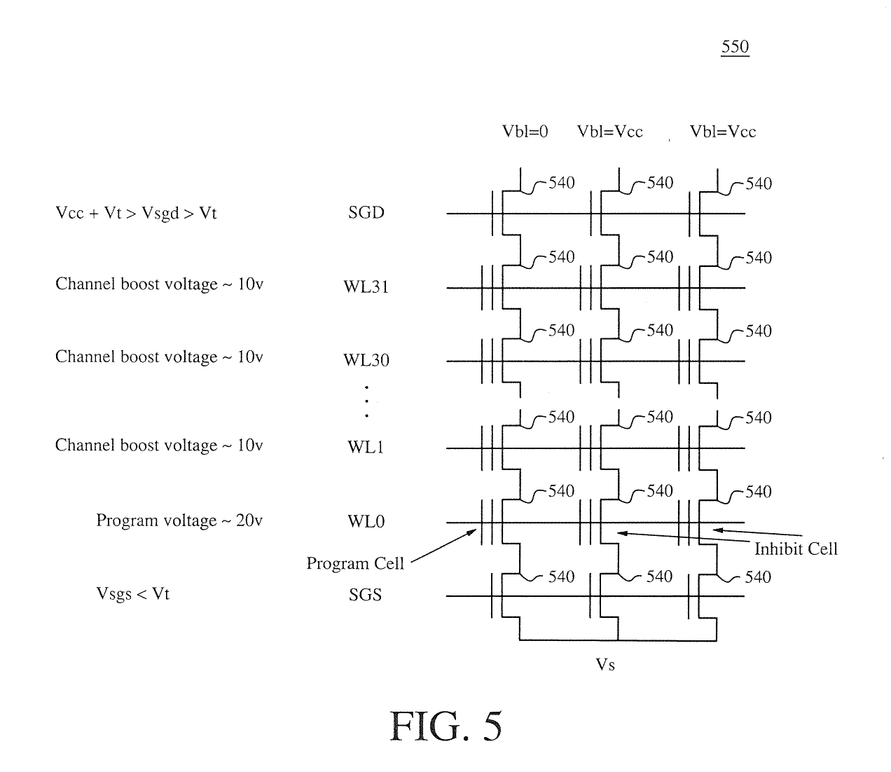

FIG. 5 illustrates an embodiment of a NAND memory cell array 550 that may be a portion of an embodiment of the NAND memory array 310 of FIG. 3. As shown, NAND memory cell array 550 includes individual cells 540. Each of the memory cells among cells 540 is coupled to a corresponding wordline and bit line. In the embodiment shown, each bit line is coupled to 34 individual cells 540, where 32 of those individual cells are memory cells. Each memory cell has a gate coupled to a corresponding word line. In each bit line, there is also a cell with a gate coupled to selective gate source SGS and another cell with a gate coupled to selective gate drain SGD.

As shown, when programming a cell, the bit line being programmed is set to 0V, the other bitlines are set to Vcc, the wordline being programmed is set to a program voltage (e.g., 20V in the embodiment shown), and the other wordlines are set to a channel boost voltage (e.g., 10V in the embodiment shown). A boost voltage is used for these cells to avoid program disturb. The SGS voltage V_{SGS} is always set to off during programming, by setting it to a voltage less than Vt. The SGD voltage VSGD is set to a voltage greater than Vt and less than Vcc+Vt, which makes SGD on for the bitlines set to 0, and off for the bitlines set to Vcc. As shown, for the cells 540 having a gate line set to the program voltage, the cell with the bitline voltage set to 0 is programmed and is referred to as the program cell, while the other cells, with bitlines voltages set to Vcc, are not programmed and are referred to as inhibit cells.

The first and last wordlines, WL0 and WL31 in this embodiment, are edge word lines, and the other wordlines are inner word lines. The inner word lines are disposed between the edge word lines. As shown, all of the word lines are disposed between the SGS and the SGD.

Although 32 word lines are shown, in other embodiments, a different number of word lines may be employed, such as 64 word lines, 16 word lines, or the like.

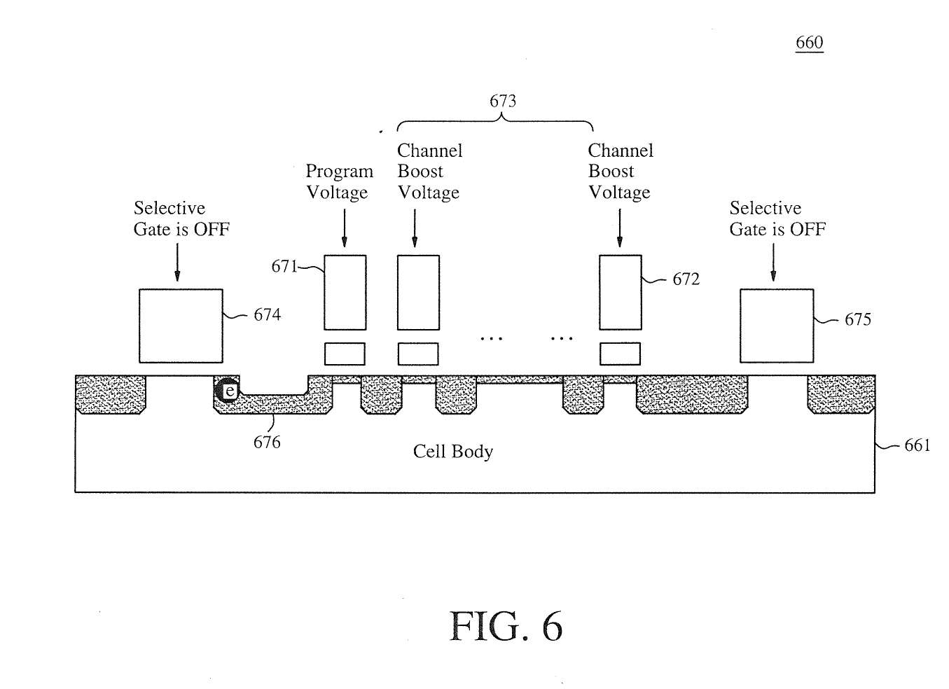

FIG. 6 shows an embodiment of a NAND memory cell column 660 which may be a column of an embodiment of NAND memory cell array 550 of FIG. 5 during programming. NAND memory cell column 660 includes cell body 661. NAND memory cell column 660 further includes selective gate 674, selective gate 675, edge word line gate 671, edge word line gate 672, and inner word line gates 673, all disposed above cell body 661. In the column shown, the bit line is not being programmed; rather, another bit line is the array is being programmed. Accordingly, the memory cell receiving the program voltage at its gate is an inhibit cell.

Cell body 661 includes a doped source/drain region 676 that is disposed between selective gate 674 and edge line gate 676. The doping in doped source/drain region 676 may have been provided previously by performing a doping implant. Cell body 661 is composed of a semiconductor such as silicon. As illustrated, a portion of doped source/drain region 676 is recessed relative to the height of the cell body 661 under selective gate 664 (and the rest of cell body 661). Preferably, doped source/drain region 676 is recess by at least 40 to 50% of the total height of the doped source/drain region, but it may be various heights in various embodiments, including at least 20 nm in some embodiments.

The recession in source/drain region 676 prevents program disturb in inhibited edge word line cells 671. The high channel potential can create gate-induced diode leakage at the edge of selective gate 674. This gate-induced diode leakage may generate hot electrons, which can potentially travel back and be injected into the edge word line cells 672 and cause word line cell program disturb, so that the word line cell unintentionally reads as programmed due to the injected hot electrons.

The recession in source/drain region 676 creates a longer distance for hot electrons to travel to reach edge word line 671. As the hot electrons travel a longer distance, they lose energy, so that the electrons will no longer be high energy and the probability of each hot electron entering the cell is lower. Accordingly, charge disturb from hot electron injection is significantly reduced. The recession in source/drain region 676 inhibits hot electron tunneling without adversely affecting the normal conduction path.

The hot electron injection charge disturb could similarly be reduced by not recessing source/drain region 676, but simply making it longer in dimension instead. However, this approach would increase the total device size. Recessing source/drain region 676 decreases hot electron injection charge disturb without increasing the device size.

The recession is source/drain 676 may be filled with a dielectric such as an oxide, a nitride, or the like. This is a different material than the source/drain 676 itself, which is a doped semiconductor material such as doped silicon.

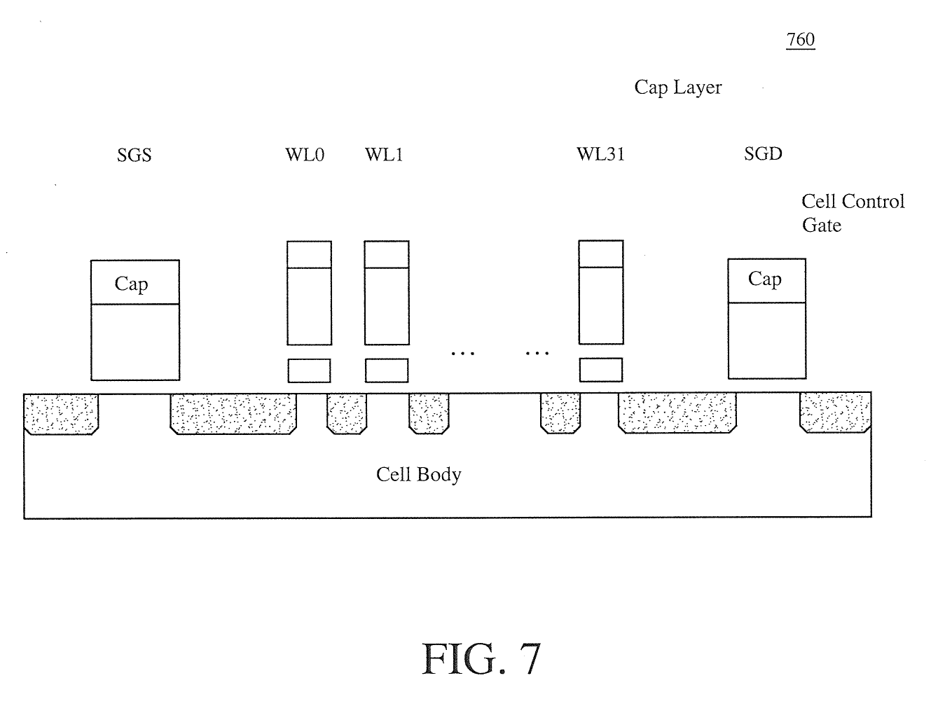

FIG. 7-9 below and the accompanying description indicate one particular way of generating a recession in source/drain region 676. However, this example is provided by way of example only, and the recession may be generated in a number of different ways in various embodiments.

FIG. 7 illustrates an embodiment of NAND memory cell column 760 in fabrication after deposition of a cap. The cap employed is to protect the gates from spacer etch in a subsequent stage. However, the cap deposition step is optional and is not included in some embodiments.

The cap film serves as a protection late to protect the gate poly-silicon film during the silicon recess etch and the spacer etch. In some embodiments, the cap is a film that is different from silicon and different from the spacer material. For example, in some embodiments, the cap film is composed of SiN, SiON, AL₂O₃, and/or the like. In some embodiments, the cap film is deposited on top of the gate poly-silicon by chemical vapor deposition (CVD), or the like. In some embodiments, the cap film is subsequently removed, and in other embodiments, the cap film remains. It is not necessary to remove the cap layer in embodiments in which metal silicide is not formed on top of the poly-silicon gate.

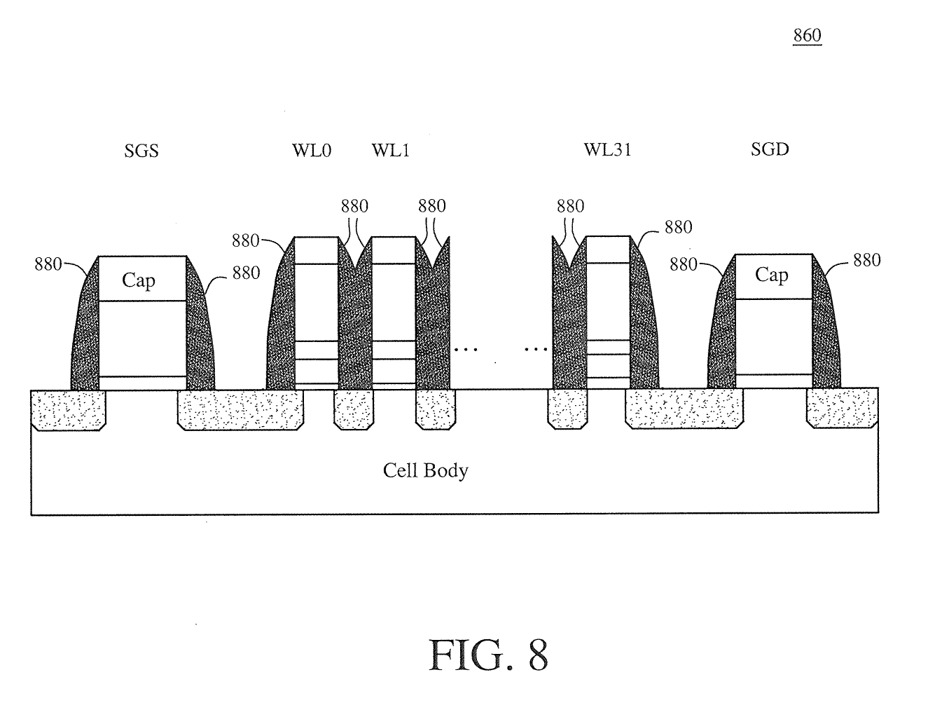

FIG. 8 shows an embodiment of NAND memory cell column 860 (which may be employed as an embodiment of NAND memory cell column 760 of FIG. 7) after array spacer deposition and etch. The spacer 880 is typically a dielectric such as an oxide or a nitride. In some embodiment, the spacer film is first deposited, and then an isotropic etch of the spacer is performed to leave the spacer on both sides of each gate.

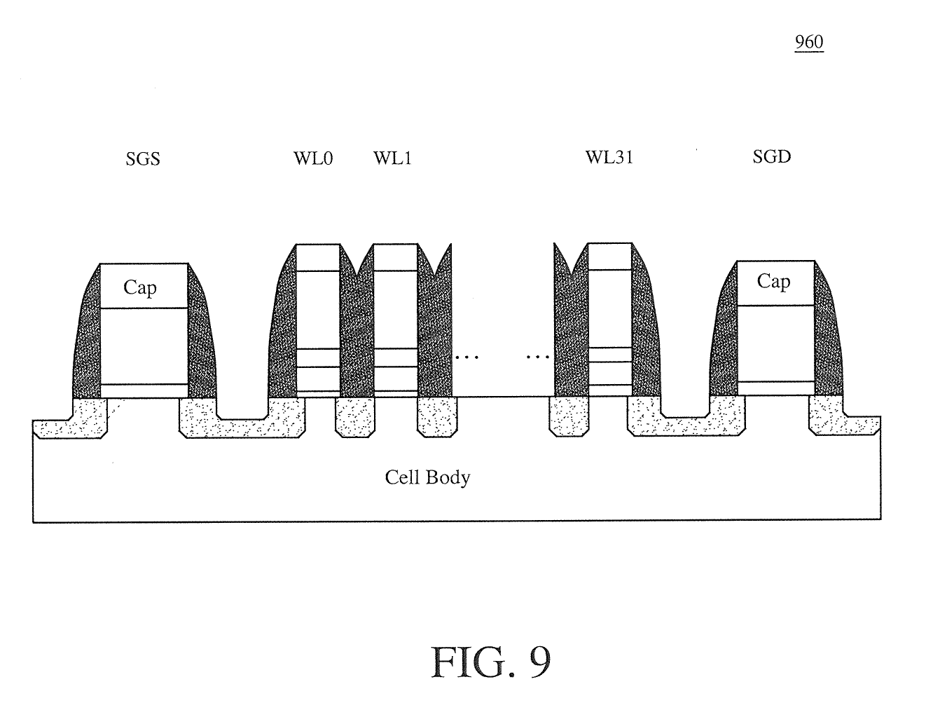

FIG. 9 illustrates an embodiment of the NAND memory cell column 960 which may be employed as an embodiment of NAND memory cell column 860 of FIG. 8 after silicon recess etch. Silicon recess etch may be performed, in some embodiments, with a dry plasma etch to anisotropically and selectively etch silicon. The chemistry of the plasma etching may be selected to selectively etch silicon. The spacers provide protection so that only the portion of the source/drain region that is desired to be etched is etched—if the entire source/drain region were etched, there would be no conduction path. Accordingly, the spacers ensure that the conduction path remains after the silicon recess etch. The recession may subsequently be filled with a dielectric by deposition or the like. In some embodiments, an additional doping implant may be added to the source/drain region after creating the recession.

The above specification, examples and data provide a description of the manufacture and use of the composition of the invention. Since many embodiments of the invention can be made without departing from the spirit and scope of the invention, the invention also resides in the claims hereinafter appended.

What is claimed is:

1. A device for storing information, comprising:
a NAND flash memory array, including:
a cell body;
a first selective gate disposed above the cell body; and
a first edge line gate, wherein the cell body includes a first doped source/drain region between the first selective gate and the first edge word line gate, wherein at least a portion of the first doped source/drain region is recessed relative to the portion of the cell body that is below the first selective gate, such that the recessed portion of the first doped source/drain region is recessed by at least twenty nanometers.

2. The device of claim 1, wherein the cell body is composed of silicon.

3. A machine-readable storage medium that includes an electronic design file that is arranged to control a fabrication of the device of claim 1.

4. A method, comprising transmitting, over a network, an article of manufacture including a machine-readable medium that includes an electronic design file that is arranged to control a fabrication of the device of claim 1.

5. The device of claim 1, wherein the NAND flash memory array further includes a plurality of word line gates disposed above the cell body, including the first edge word line gate, a second edge word line gate, and a plurality of inner word line gates disposed between the first edge word line gate and the second edge word line gate.

6. The device of claim 5, wherein the NAND flash memory array further includes a second selective gate disposed above the cell body, wherein the plurality of word line gates are disposed between the first selective gate and the second selective gate.

7. The device of claim 1, further comprising a dielectric that fills in the recession in the first doped source/drain region.

8. The device of claim 7, wherein the dielectric includes at least one of an oxide or a nitride.

9. A method for device fabrication, comprising:
creating a recession in a doped source/drain region, wherein the doped source/drain region is a doped portion of a cell body, the doped source/drain region is between a first selective gate and a first edge word line gate, and wherein the recession is at least twenty nanometers.

10. The method for device fabrication of claim 9, further comprising:
depositing a spacer;
performing an anisotropic etch of the spacer such that the spacer remains on the sides of the first selective gate and the sides of first edge word line gate, wherein creating the recession in the doped source/drain region includes performing a dry plasma etch to anisotropically etch silicon in the doped sour/drain region to create the recession after performing the anisotropic etch of the spacer.

11. The method of claim 9, further comprising:
depositing a dielectric to fill the recession in the doped source/drain region.

12. The method of claim 9, further comprising:
depositing a cap layer over at least the first selective gate before creating the recession in the doped source/drain region, wherein the cap layer acts as a protective layer over at least the first selective gate at least while the recession is created in the doped source/drain region.

13. The method of claim 9, further comprising:
prior to generating the recession, performing a first doping implant to provide the doping for the doped source/drain region; and
after creating the recession, performing a second doping implant.
